(19) United States
(12) Patent Application Publication
(10) Pub. No.: US 2026/0190398 A1
(43) Pub. Date: Jul. 2, 2026

(54) THIN FILM TRANSISTOR HAVING SLOPE PART, METHOD FOR MANUFACTURING THE SAME, AND DISPLAY APPARATUS COMPRISING THE SAME

(71) Applicant: LG Display Co., Ltd., Seoul (KR)

(72) Inventors: JuHeyuck BAECK, Paju-si (KR); Dohyung LEE, Paju-si (KR); GaWon YANG, Paju-si (KR)

(73) Assignee: LG Display Co., Ltd., Seoul (KR)

(21) Appl. No.: 19/385,627

(22) Filed: Nov. 11, 2025

(30) Foreign Application Priority Data
Dec. 26, 2024 (KR) 10-2024-0197525

(51) Int. Cl. H10D 30/67; H10D 30/01; H10K 59/121

(52) U.S. Cl. CPC H10D 30/6757; H10D 30/0314; H10D 30/6713; H10D 30/6723; H10D 30/6731; H10D 30/6736; H10D 30/6755; H10K 59/1213

(57) ABSTRACT

A thin film transistor includes an active layer having a plurality of first oxide semiconductor layers and a plurality of second oxide semiconductor layers alternately stacked, and a gate electrode spaced apart from and at least partially overlapping the active layer. The active layer includes a channel part overlapping the gate electrode, the channel part having a slope part in which the thickness gradually changes. The second oxide semiconductor layer has a higher mobility than the first oxide semiconductor layer, thereby achieving excellent current characteristics and stability. Another embodiment provides a method of manufacturing the thin film transistor, in which the slope part is formed through controlled patterning and etching of the oxide semiconductor layers, and further provides a display apparatus including the thin film transistor to improve gray scale control and operational reliability.

### CROSS-REFERENCE TO RELATED APPLICATION

This application claims the benefit of priority of the Republic of Korea Patent Application No. 10-2024-0197525 filed on Dec. 26, 2024, which is hereby incorporated by reference in its entirety.

### BACKGROUND

### Technical Field

The present disclosure relates to a thin film transistor having a slope part, a method for manufacturing the same, and a display apparatus including the thin film transistor.

### Description of the Related Art

The transistors are widely used as switching or driving devices in electronic devices. In particular, thin film transistors (TFT) may be manufactured on glass or plastic substrates, making them widely used as switching elements in display apparatuses such as liquid crystal displays (LCD) and organic light emitting devices (OLED).

Thin film transistors may be classified into amorphous silicon thin film transistors in which amorphous silicon is used as the active layer, polycrystalline silicon thin film transistors in which polycrystalline silicon is used as the active layer, and oxide semiconductor thin film transistors in which oxide semiconductor is used as the active layer, based on the material constituting the active layer.

Among these, oxide semiconductor thin film transistor, which has high mobility and exhibit large resistance variation depending on the oxygen content, has the advantage of easily achieving desired physical property. Furthermore, since the oxide constituting the active layer may be formed at relatively low temperatures during the manufacturing process of Oxide Semiconductor TFT, manufacturing costs are low. Due to the nature of oxides, Oxide Semiconductors are transparent, making them advantageous for implementing transparent displays.

Recently, the electronic products are becoming more highly integrated, and the demand for high resolution display apparatuses is increasing. High performance thin film transistors with excellent current characteristic are required for high integration and high resolution, and miniaturization of thin film transistors is necessary.

When the high mobility oxide semiconductor materials are used to manufacture high performance and small sized thin film transistors, the stability of the threshold voltage (Vth) may deteriorate, and the threshold voltage may shift due to light, causing a negative shift of the threshold voltage (Vth), making it difficult to set the on voltage of the thin film transistor. Consequently, it may be difficult for the thin film transistor to perform a stable switching function.

### BRIEF SUMMARY

The present disclosure relates to a thin film transistor that includes an active layer formed by alternately stacking high mobility and low mobility oxide semiconductor layers. The oxygen content in each layer is precisely controlled through atomic layer deposition by adjusting the oxygen partial pressure during deposition. This configuration allows independent tuning of carrier mobility and stability for each layer, resulting in excellent current characteristics and improved electrical reliability compared to conventional oxide semiconductor transistors formed from a single material.

One aspect of the structure is the presence of a slope in the channel region, where the thickness gradually increases from the source side to the drain side. This sloped configuration produces a distributed electric field and enables multiple oxide layers to function as subchannels with different mobilities. As a result, the device exhibits a large subthreshold swing, a stable and positive threshold voltage, and reduced drain side stress. These effects collectively improve performance and operational stability under bias or light exposure.

The sloped channel is formed using a process that employs both positive and negative photoresist materials with a halftone mask exposure to achieve controlled etching of the oxide multilayer. This method enables precise formation of the desired slope while maintaining manufacturing simplicity. The resulting thin film transistor provides enhanced current control and gray scale accuracy when applied to display driving circuits, contributing to stable and reliable operation in display devices such as organic light emitting diode and liquid crystal displays.

Various embodiments of the present disclosure provide a thin film transistor having excellent stability and a large s-factor (subthreshold swing; S.S), even with excellent current characteristic.

Various embodiments of the present disclosure provide a thin film transistor having excellent current characteristic and a large s-factor by forming an active layer by alternately disposing high mobility oxide semiconductor layers and low mobility oxide semiconductor layers, and forming a slope part in a channel part of the active layer.

In addition, one embodiment of the present disclosure is to provide a thin film transistor having excellent current characteristic and excellent stability, including a plurality of high-mobility oxide semiconductor layers and a plurality of low-mobility oxide semiconductor layers alternately disposed.

One embodiment of the present disclosure is to provide a manufacturing method for a thin film transistor.

One embodiment of the present disclosure is to provide a display apparatus having excellent reliability, including the thin film transistor.

One embodiment of the present disclosure for achieving the above described technical problem provides a thin film transistor including an active layer including a plurality of first oxide semiconductor layers and a plurality of second oxide semiconductor layers, and a gate electrode spaced apart from the active layer and at least partially overlapping the active layer, wherein the active layer includes a channel part overlapping the gate electrode, wherein the channel part has a slope part, and wherein the second oxide semiconductor layer has a higher mobility than the first oxide semiconductor layer.

The plurality of first oxide semiconductor layers and the plurality of second oxide semiconductor layers may be alternately stacked.

An oxygen content ratio of the first oxide semiconductor layer may be higher than an oxygen content ratio of the second oxide semiconductor layer, wherein the oxygen content ratio of the first oxide semiconductor layer is calculated, on a molar basis, as a ratio of the oxygen element to the total elements contained in the first oxide semiconductor layer, and wherein the oxygen content ratio of the second oxide semiconductor layer may be calculated, on a molar basis, as a ratio of the oxygen element to the total elements contained in the second oxide semiconductor layer.

Each of the plurality of first oxide semiconductor layers and each of the plurality of second oxide semiconductor layers may have a thickness of 1.5 to 2.5 nm.

The first oxide semiconductor layer includes at least one of an IGZO (InGaZnO) based oxide semiconductor material, a GZO (GaZnO) based oxide semiconductor material, an IGO (InGaO) based oxide semiconductor material, and a GZTO (GaZnSnO) based oxide semiconductor material, and when the oxide semiconductor material included in the first oxide semiconductor layer includes gallium (Ga) and indium (In), the concentration of gallium (Ga) may be higher than the concentration of indium (In) on a molar basis [Ga concentration>In concentration].

The second oxide semiconductor layer includes at least one of an InO based oxide semiconductor material, an IZO (InZnO) based oxide semiconductor material, an IGO (InGaO) based oxide semiconductor material, an ITZO (InSnZnO) based oxide semiconductor material, an IGZO (InGaZnO) based oxide semiconductor material, an IGZTO (InGaZnSnO) based oxide semiconductor material, a FIGZO (FelnGaZnO) based oxide semiconductor material, and a FIZO (FeInZnO) based oxide semiconductor material, and when the oxide semiconductor material included in the second oxide semiconductor layer includes gallium (Ga) and indium (In), the concentration of indium (In) may be higher than the concentration of gallium (Ga) on a molar basis [Ga concentration<In concentration].

The active layer includes a first connection part connected to a first side of the channel part and a second connection part connected to a second side of the channel part, and a thickness of the first side is smaller than a thickness of the second side.

The first connection part may be connected to a source electrode, and the second connection part may be connected to a drain electrode.

The thickness of the channel part may gradually increase in a direction from the first side toward the second side.

The number of first oxide semiconductor layers disposed at the second side may be greater than the number of first oxide semiconductor layers disposed at the first side, and the number of second oxide semiconductor layers disposed at the second side may be greater than the number of second oxide semiconductor layers disposed at the first side.

The channel part may include a flat part and a slope part, the flat part is a portion having the same thickness from the first side to the second side, the slope part is disposed on the flat part, and the thickness of the first side and the thickness of the second side in the slope part may be different.

The channel part may include a first channel part and a second channel part, the first channel part is connected to the first side and may have a slope, and the second channel part is connected to the second side and may not have a slope.

The thickness of the second channel part may be uniform.

The thickness of the second channel part may be equal to a thickness of the second connection part

Another embodiment of the present disclosure includes forming an oxide semiconductor material layer on a substrate, forming a positive photoresist pattern and a negative photoresist pattern on the oxide semiconductor material layer, partially exposing the positive photoresist pattern and the negative photoresist pattern, developing the partially exposed positive photoresist pattern and the negative photoresist pattern, etching the oxide semiconductor material layer using the developed positive photoresist pattern and the negative photoresist pattern as a mask to form an active layer, and forming a gate electrode spaced apart from the active layer on the active layer, wherein forming the oxide semiconductor material layer comprises alternately stacking a plurality of first oxide semiconductor material layers and a plurality of second oxide semiconductor material layers, wherein in developing the positive photoresist pattern and the negative photoresist pattern, an exposed portion of the positive photoresist pattern is removed, wherein the second oxide semiconductor layer has a higher mobility than the first oxide semiconductor layer, wherein the active layer includes a channel part overlapping the gate electrode, and wherein the channel part has a sloping surface.

Another embodiment of the present disclosure provides a display apparatus including the above thin film transistor.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a cross-sectional view of a thin film transistor according to one embodiment of the present disclosure.

FIG. 2 is an enlarged cross-sectional view of the channel part of the thin film transistor illustrated in FIG. 1.

FIG. 3 is a partial cross-sectional view of the channel part and gate electrode of the thin film transistor illustrated in FIG. 1.

FIG. 4 is a cross-sectional view of a thin film transistor according to another embodiment of the present disclosure.

FIG. 5 is an enlarged cross-sectional view of the channel part of the thin film transistor illustrated in FIG. 4.

FIG. 6 is a cross-sectional view of a thin film transistor according to another embodiment of the present disclosure.

FIG. 7 is a cross-sectional view of a thin film transistor according to another embodiment of the present disclosure.

FIG. 8 is a cross-sectional view of a thin film transistor according to a comparative example.

FIG. 9 is a voltage-current graph for thin film transistors.

FIG. 10A to FIG. 10M are cross-sectional views illustrating a manufacturing method for a thin film transistor according to one embodiment of the present disclosure.

FIG. 11 is a schematic diagram of a display apparatus according to another embodiment of the present disclosure.

FIG. 12 is a circuit diagram for one pixel of FIG. 11.

### DETAILED DESCRIPTION

In addition to the effects mentioned above, other features and advantages of the present disclosure are described below or may be clearly understood by those skilled in the art to which the present disclosure pertains from such description and explanation.

The advantages and features of the present disclosure, and the methods for achieving them, will become clearer with reference to the embodiments described in detail below, along with the accompanying drawings. However, the present disclosure is not limited to the embodiments disclosed below and may be implemented in various other forms. These embodiments are provided to ensure that the disclosure of the present disclosure is complete and to facilitate the understanding of the disclosure by those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout the specification, identical components may be designated by identical reference numerals. Furthermore, in describing the present disclosure, if a detailed description of a related known technology is deemed to unnecessarily obscure the gist of the present disclosure, the detailed description will be omitted.

In this specification, when the words “include,” “have,” and “consist of” are used, other parts may be added, unless the expression “only” is used. When a component is expressed in the singular, the plural is included unless otherwise explicitly stated.

When interpreting a component, it is interpreted as including the error range even if there is no separate explicit description.

When describing a positional relationship, for example, when the positional relationship between two parts is described as ‘on top of’, ‘upper part of’, ‘lower part of’, ‘next to’, etc., one or more other parts may be located between the two parts, unless the expression ‘right’ or ‘directly’ is used.

Spatially relative terms such as “below,” “beneath,” “lower,” “above,” and “upper” may be used to easily describe the relationship of one element or component to another, as illustrated in the drawings. Spatially relative terms should be understood to include different orientations of the elements during use or operation in addition to the orientations depicted in the drawings. For example, if an element depicted in the drawings were flipped over, an element described as “below” or “beneath” another element could end up being placed “above” the other element. Thus, the exemplary term “below” can encompass both the above and below directions. Similarly, the exemplary term “above” can encompass both the above and below directions.

When describing a temporal relationship, for example, when the temporal relationship is described as ‘after’, ‘following’, ‘next to’, ‘before’, etc., it can also include cases where it is not continuous, as long as the expression ‘immediately’ or ‘directly’ is not used.

While terms like “first” and “second” are used to describe various components, these components are not limited by these terms. These terms are used merely to distinguish one component from another. Therefore, a “first” component referred to below may also be a “second” component within the technical scope of the present disclosure.

The term “at least one” should be understood to include all possible combinations of one or more associated items. For example, “at least one of the first, second, and third items” can mean any combination of items that may be represented by two or more of the first, second, and third items, as well as each of the first, second, and third items.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The features of each of the various embodiments of the present disclosure may be partially or wholly combined or combined with each other, and various technical connections and operations are possible, and each embodiment may be implemented independently of each other or implemented together in a related relationship.

Hereinafter, a thin film transistor and a display apparatus including the same according to an embodiment of the present disclosure will be described in detail with reference to the attached drawings. When adding reference numerals to components in each drawing, identical components may have the same numerals as much as possible even if they are shown in different drawings.

In embodiments of the present disclosure, the source electrode and the drain electrode are distinguished for convenience of explanation, but the source electrode and the drain electrode may be interchanged. For example, the source electrode according to one embodiment may become the drain electrode in another embodiment, and the drain electrode according to one embodiment may become the source electrode in another embodiment.

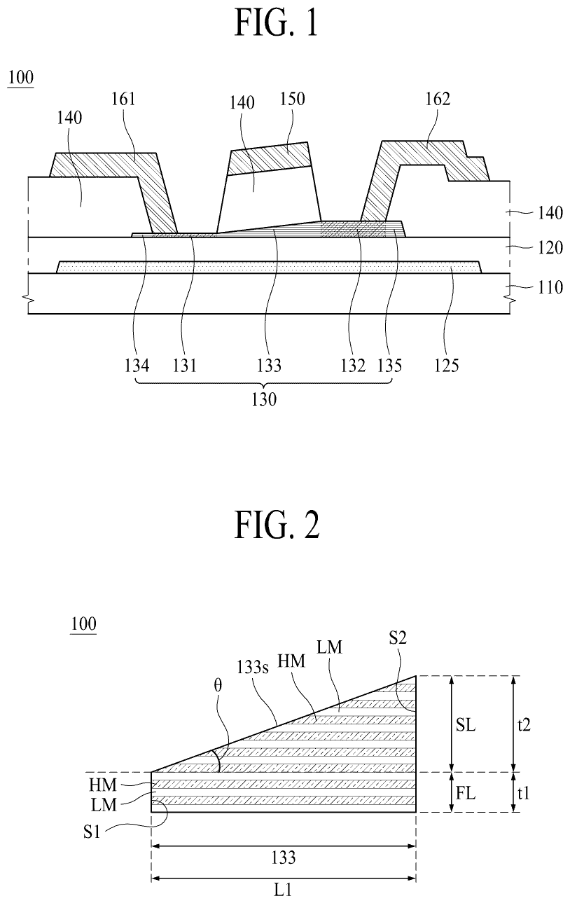

FIG. 1 is a cross-sectional view of a thin film transistor 100 according to one embodiment of the present disclosure, and FIG. 2 is an enlarged cross-sectional view of a channel part 133 of the thin film transistor 100 illustrated in FIG. 1.

A thin film transistor 100 according to one embodiment of the present disclosure includes an active layer 130 having a plurality of first oxide semiconductor layers LM and a plurality of second oxide semiconductor layers HM, and a gate electrode 150 spaced apart from the active layer 130 and at least partially overlapping the active layer 130.

Referring to FIG. 1, a thin film transistor 100 may be disposed on a substrate 110. Any substrate 110 may be used without limitation as long as it supports the thin film transistor 100.

The glass or plastic may be used as the substrate 110. A transparent plastic having flexible property may be used as the substrate 110. Among plastics, for example, when polyimide is used as the substrate 110, considering that a high temperature deposition process is performed on the substrate 110, a heat-resistant polyimide that can withstand high temperatures may be used.

A light shielding layer 125 may be disposed on the substrate 110. The light shielding layer 125 has light blocking property. The light shielding layer 125 may block light incident from the substrate 110 and thereby protect the active layer 130. The light shielding layer 125 may be made of a metal or a metal alloy. The light shielding layer 125 may also be omitted.

The buffer layer 120 is disposed on the light shielding layer 125. The buffer layer 120 covers the upper surface of the substrate 110 and the upper surface of the light shielding layer 125. If the light shielding layer 125 is omitted, the buffer layer 120 may also be omitted.

The buffer layer 120 may be made of an insulating material. For example, the buffer layer 120 may include at least one of insulating materials such as silicon oxide, silicon nitride, and metal oxide. The buffer layer 120 may protect the active layer 130 by blocking air and moisture. The surface of the upper portion of the substrate 110 may be made uniform by the buffer layer 120.

The active layer 130 may be disposed on the buffer layer 120. The active layer 130 may be disposed on the substrate 110.

The active layer 130 includes a first oxide semiconductor layer LM and a second oxide semiconductor layer HM on the first oxide semiconductor layer LM. The second oxide semiconductor layer HM may have a mobility that is different from the first oxide semiconductor layer LM may have different mobilities.

In detail, the active layer 130 includes a plurality of first oxide semiconductor layers LM and a plurality of second oxide semiconductor layers HM. The second oxide semiconductor layers HM may have a greater mobility than the first oxide semiconductor layers LM.

As illustrated in FIG. 2, a plurality of first oxide semiconductor layers LM and a plurality of second oxide semiconductor layers HM may be alternately stacked. The active layer 130 may have a structure in which a plurality of first oxide semiconductor layers LM and a plurality of second oxide semiconductor layers HM are alternately stacked. For example, the first oxide semiconductor layers LM may be disposed at the bottom and at the top of the active layer 130.

The active layer 130 may include 5 to 10 first oxide semiconductor layers LM and 5 to 10 second oxide semiconductor layers HM. Each of the plurality of first oxide semiconductor layers LM may have a thickness of 1.5 to 2.5 nm. In addition, each of the plurality of second oxide semiconductor layers HM may have a thickness of 1.5 to 2.5 nm.

The active layer 130 may have a total of 10 to 20 layers. The total number of layers of the plurality of first oxide semiconductor layers LM and the plurality of second oxide semiconductor layers HM included in the active layer 130 may be 10 to 20. In the range of 10 to 20 layers, the plurality of first oxide semiconductor layers LM and the plurality of second oxide semiconductor layers HM may be alternately stacked to form the active layer 130. For example, both the top and the bottom of the active layer 130 may be formed by the first oxide semiconductor layers LM.

For example, after a first oxide semiconductor material layer for forming a first oxide semiconductor layer LM and a second oxide semiconductor material layer for forming a second oxide semiconductor layer HM are formed on a substrate 110, the first oxide semiconductor material layer and the second oxide semiconductor material layer may be patterned to form an active layer 130.

The first oxide semiconductor layer LM and the second oxide semiconductor layer HM may be formed by an atomic layer deposition (ALD) method. A plurality of first oxide semiconductor layers LM and a plurality of second oxide semiconductor layers HM may be alternately formed by an atomic layer deposition (ALD) method to form an active layer 130.

When the atomic layer deposition (ALD) method is applied, the thickness of the first oxide semiconductor layer LM and the thickness of the second oxide semiconductor layer HM may be independently controlled. In addition, when the atomic layer deposition (ALD) method is applied, the oxygen (O) content included in the first oxide semiconductor layer LM and the oxygen (O) content included in the second oxide semiconductor layer HM may be independently controlled.

The mobility of the first oxide semiconductor layer LM and the second oxide semiconductor layer HM may be controlled depending on the oxygen (O) content. In the atomic layer deposition (ALD) process for forming the first oxide semiconductor layer LM and the second oxide semiconductor layer HM, the oxygen content of the first oxide semiconductor layer LM and the second oxide semiconductor layer HM may be controlled by adjusting the content of oxygen (O₂) or ozone (O₃), which is one of the reaction gases.

When the content of oxygen (O₂) or ozone (O₃), which is a reaction gas used in the atomic layer deposition (ALD) process, is increased, the oxygen content included in the first oxide semiconductor layer LM or the second oxide semiconductor layer HM may be increased. On the other hand, when the content of oxygen (O₂) or ozone (O₃), which is a reaction gas used in the ALD process, is decreased, the oxygen content included in the first oxide semiconductor layer LM or the second oxide semiconductor layer HM may be decreased. The content of oxygen (O₂) or ozone (O₃) may be controlled by adjusting the partial pressure of oxygen (O₂) or ozone (O₃).

For example, when the partial pressure of oxygen (O₂) or ozone (O₃) in the ALD process is high, it can be said that the content of oxygen (O₂) or ozone (O₃) in the reaction gas is high, and as a result, an oxide semiconductor having a high oxygen content may be formed. On the other hand, when the partial pressure of oxygen (O₂) or ozone (O₃) in the ALD process is low, the content of oxygen (O₂) or ozone (O₃) in the reaction gas is low, and as a result, an oxide semiconductor having a low oxygen content may be formed.

As the oxygen content in the oxide semiconductor layer increases, the oxygen content relative to the metal, which is constituting the oxide semiconductor layer, approaches to a level that the oxygen is stoichiometrically saturated state, and thus the amount of oxygen vacancy (Vo) decreases. As a result, the mobility of the oxide semiconductor layer may decrease.

On the other hand, if the content of oxygen contained in the oxide semiconductor layer is reduced, the content of oxygen relative to the metal, which is constituting the oxide semiconductor layer, becomes lower than the level that the oxygen is stoichiometrically saturated state, and thus the amount of oxygen vacancy (Vo) may increase. As a result, the mobility of the oxide semiconductor layer may increase.

According to one embodiment of the present disclosure, the first oxide semiconductor layer LM may be an oxygen (O) rich layer containing a large amount of oxygen, and the second oxide semiconductor layer HM may be an oxygen (O) poor layer containing a small amount of oxygen. According to one embodiment of the present disclosure, the oxygen content ratio of the first oxide semiconductor layer LM may be higher than the oxygen content ratio of the second oxide semiconductor layer HM. Here, the oxygen content ratio of the first oxide semiconductor layer LM may be calculated as the ratio of the oxygen element to the total elements contained in the first oxide semiconductor layer LM on a mol basis. In addition, the oxygen content ratio of the second oxide semiconductor layer HM may be calculated as the ratio of the oxygen element to the total elements contained in the second oxide semiconductor layer HM on a molar mol basis.

The first oxide semiconductor layer LM having a high oxygen concentration may have excellent stability. Since, in the first oxide semiconductor layer LM, relatively large portion of metal elements can form stable bonds with oxygen, the first oxide semiconductor layer LM may have stable electrical characteristic. In addition, the first oxide semiconductor layer LM has a low concentration of oxygen vacancy (Vo), and thus may have relatively low mobility. The first oxide semiconductor layer LM can have a non-conductive characteristic when the oxygen vacancies are completely removed or when the first oxide semiconductor layer LM is manufactured under oxygen-excess conditions.

The second oxide semiconductor layer HM has a higher concentration of oxygen vacancy (Vo) than the first oxide semiconductor layer LM, and may have higher mobility than the first oxide semiconductor layer LM. The current characteristic of the thin film transistor 100 may be improved by the second oxide semiconductor layer HM.

The first oxide semiconductor layer LM may include a low mobility oxide semiconductor material. According to one embodiment of the present disclosure, the first oxide semiconductor layer LM may include at least one of an IGZO (InGaZnO) based oxide semiconductor material, a GZO (GaZnO) based oxide semiconductor material, an IGO (InGaO) based oxide semiconductor material, and a GZTO (GaZnSnO) based oxide semiconductor material. When the oxide semiconductor material of the first oxide semiconductor layer LM includes gallium (Ga) and indium (In), the concentration of gallium (Ga) may be higher than the concentration of indium (In) on a molar basis [Ga concentration>In concentration].

The first oxide semiconductor layer LM may have a mobility ranging 5 cm²/V·s to 20 cm²/V·s. In more detail, the first oxide semiconductor layer LM may have a mobility in a range of 5 to 15 cm²/V·s, or may have a mobility of about 10 cm²/V·s.

The second oxide semiconductor layer HM may include a high-mobility oxide semiconductor material. According to one embodiment of the present disclosure, the second oxide semiconductor layer HM may include at least one of an InO based oxide semiconductor material, an IZO (InZnO) based oxide semiconductor material, an ITZO (InSnZnO) based oxide semiconductor material, an IGZO (InGaZnO) based oxide semiconductor material, an IGO (InGaO) based oxide semiconductor material, an IGZTO (InGaZnSnO) based oxide semiconductor material, a FIGZO (FeInGaZnO) based oxide semiconductor material, and a FIZO (FeInZnO) based oxide semiconductor material. When the oxide semiconductor material of the second oxide semiconductor layer HM includes gallium (Ga) and indium (In), the concentration of indium (In) may be higher than the concentration of gallium (Ga) on a molar basis [Ga concentration<In concentration].

In detail, an indium-based oxide semiconductor material, which has an indium (In) content of 30 atomic % (at %) or more based on the total number of metal atoms, may be used to form the second oxide semiconductor layer HM. The second oxide semiconductor layer HM may include, for example, at least one of an InO based oxide semiconductor material, an IZO (InZnO) based oxide semiconductor material, an ITZO (InSnZnO) based oxide semiconductor material, an IGZO (InGaZnO) based oxide semiconductor material, an IGZTO (InGaZnSnO) based oxide semiconductor material, a FIGZO (FelnGaZnO) based oxide semiconductor material, and a FIZO (FeInZnO) based oxide semiconductor material, in which a content of the indium (In) is 30 atomic % (at %) or more based on the total number of metal atoms.

In detail, the second oxide semiconductor layer HM may include an indium-based oxide semiconductor material having an indium (In) content of 50 at % or more based on the total metal atoms.

According to an embodiment of the present disclosure, the second oxide semiconductor layer HM may have a mobility greater than that of the first oxide semiconductor layer LM by 3 cm²/V·s or more. In more detail, the second oxide semiconductor layer HM may have a mobility greater than that of the first oxide semiconductor layer LM by 5 cm²/V·s or more, or may have a mobility greater by 10 cm²/V·s or more.

The specific mobility value of the second oxide semiconductor layer HM may vary depending on the mobility of the first oxide semiconductor layer LM.

For example, the second oxide semiconductor layer HM may have a mobility of 20 cm²/V·s or more. In detail, the second oxide semiconductor layer HM may have a mobility in a range of about 20 to 50 cm²/V·s. In more detail, the second oxide semiconductor layer HM may have a mobility in a range of 20 to 40 cm²/V·s, or in a range of 20 to 30 cm²/Vs, or may have a mobility of 50 cm²/V·s or more. In addition, the second oxide semiconductor layer HM may have a mobility in a range of 50 to 100 cm²/V·s. For example, when a crystalline InO-based oxide semiconductor material is used for the second oxide semiconductor layer HM, the second oxide semiconductor layer HM may have a mobility of about 50 to 100 cm²/V·s.

In addition, when light is irradiated on the active layer, carriers of the active layer may increase. In order to prevent the threshold voltage (Vth) of the thin film transistor 100 from shifting in the negative (−) direction due to an increase in carriers caused by light irradiation, the second oxide semiconductor layer HM may have a relatively large energy band gap. For example, the second oxide semiconductor layer HM may have an energy band gap of 3.5 eV or more, or may have an energy band gap of 4 eV or more. In addition, according to an embodiment of the present disclosure, since the first oxide semiconductor layer LM sufficiently contains oxygen (O), the first oxide semiconductor layer LM may not have or may hardly have a deep donor state, which is a state that reacts to light, and thus the first oxide semiconductor layer LM may have excellent stability against light.

When the energy band gap of the second oxide semiconductor layer HM is 4 eV or more, even though light is irradiated on the second oxide semiconductor layer HM, electrons in a deep donor state are prevented from being converted to a shallow donor state, thereby preventing an increase in unnecessary oxygen vacancy (Vo) and preventing the threshold voltage (Vth) of the thin film transistor 100 from shifting in a negative (−) direction. As a result, the thin film transistor 100 may have excellent stability.

According to one embodiment of the present disclosure, the active layer 130 may have a slope. The slope may be formed across a plurality of first oxide semiconductor layers LM and a plurality of second oxide semiconductor layers HM. In addition, the active layer 130 may have a sloping surface 133s. The sloping surface 133s may be formed across a plurality of first oxide semiconductor layers LM and a plurality of second oxide semiconductor layers HM.

The active layer 130 may have a slope angle θ. The slope angle θ may be referred to as representing the degree to which the sloping surface 133s is tilted with respect to the upper surface of the substrate 110.

According to one embodiment of the present disclosure, the slope angle of the slope formed in the first oxide semiconductor layer LM and the slope angle of the slope formed in the second oxide semiconductor layer HM are not distinguished, and both are referred to as the slope angle θ.

The active layer 130 includes a channel part 133 that overlaps with the gate electrode 150. The channel part 133 functions as a channel of the thin film transistor 100. The channel part 133 has semiconductor property. The channel part 133 may overlap with the light shielding layer 125.

The active layer 130 may include a first connection part 131 connected to a first side S1 of the channel part 133 and a second connection part 132 connected to a second side S2 of the channel part 133.

The first side S1 and the second side S2 of the channel part 133 may be referred to as opposite ends of the channel part 133 along the longitudinal direction, respectively. The positions of the first side S1 and the second side S2 may be defined by the gate electrode 150. The longitudinal direction of the channel part 133 may be referred to as the direction in which carriers move. When the carriers are electrons, the longitudinal direction of the channel part 133 may be the opposite direction to the direction of the current. According to one embodiment of the present disclosure, the shortest line connecting the first connection part 131 and the second connection part 132 may be referred to as the longitudinal direction of the channel part 133.

Referring to FIG. 1 and FIG. 2, the first side S1 has a smaller thickness than the second side S2. In detail, the thickness t1 of the first side S1 of the channel part 133 is smaller than the thickness t1+t2 of the second side S2 of the channel part 133.

The channel part 133 has a slope. In detail, it may be said that the channel part 133 has a sloping surface 133s. In the process of forming the active layer 130, by depositing an active material layer on a substrate 110 using an oxide semiconductor material and then patterning the active material layer to form the active layer 130, a slope may be formed in the channel part 133.

The slope of the channel part 133 may have a predetermined slope angle θ based on the upper surface of the substrate 110. According to one embodiment of the present disclosure, the angle between the upper surface of the substrate 110 and the sloping surface 133s of the channel part 133 is referred to as the slope angle θ.

As illustrated in FIG. 2, the thickness of the channel part 133 may gradually increase in the direction from the first side S1 toward the second side S2. The channel part 133 may have a thickness gradient. The channel part 133 may have a thickness gradient that gradually increases in the direction from the first side S1 toward the second side S2.

The channel part 133 may have a length of L1. Referring to FIG. 2, the thickness of the channel part 133 may gradually increase over the entire length L1 of the channel part 133 in the direction from the first side S1 to the second side S2.

The slope angle θ, which is the angle between the upper surface of the substrate 110 and the sloping surface 133s of the channel part 133, may vary depending on the length L1 of the channel part 133, and the number of the first oxide semiconductor layers LM and the number of the second oxide semiconductor layers HM stacked in the channel part 133. For example, when the length L1 of the channel part 133 becomes shorter, the slope angle θ may increase. According to one embodiment of the present disclosure, the slope angle θ may be 0.15° or more and 45° or less. The slope angle θ may be in the range of 0.15° to 15°, may be in the range of 0.15° to 10°, may be in the range of 0.15° to 1.0°, or may be in the range of 0.15° to 0.60°. The slope angle θ may in a range of 0.19° to 0.57°.

According to one embodiment of the present disclosure, the number of first oxide semiconductor layers LM disposed at the second side S2 is greater than the number of first oxide semiconductor layers LM disposed at the first side S1. In addition, the number of second oxide semiconductor layers HM disposed at the second side S2 is greater than the number of second oxide semiconductor layers HM disposed at the first side S1.

Referring to FIG. 2, the number of first oxide semiconductor layers LM disposed at the first side S1 is 3, and the number of first oxide semiconductor layers LM disposed at the second side S2 is 9. Thus, the number 9 of first oxide semiconductor layers LM disposed at the second side S2 is greater than the number 3 of first oxide semiconductor layers LM disposed at the first side S1.

Also, referring to FIG. 2, the number of second oxide semiconductor layers HM disposed at the first side S1 is 2, and the number of second oxide semiconductor layers HM disposed at the second side S2 is 8. Thus, the number of second oxide semiconductor layers HM disposed at the second side S2 is greater than the number of second oxide semiconductor layers HM disposed at the first side S1.

Referring to FIG. 2, the channel part 133 may have a flat layer FL and a sloped layer SL. The flat layer FL is a portion having the same thickness from the first side S1 to the second side S2. Referring to FIG. 2, the flat layer FL may include three first oxide semiconductor layers LM and two second oxide semiconductor layers HM. The flat layer FL may have a thickness of t1 throughout the flat layer FL.

The slope layer SL may be disposed on the flat layer FL. The thickness of the first side S1 and the thickness t2 of the second side of the slope layer SL may be different. Referring to FIG. 2, the thickness of the first side S1 in a region of the slope layer SL is 0 (zero), and the thickness of the second side in the region of the slope layer SL is t2 (t2>0).

The first connection part 131 and the second connection part 132 may be respectively disposed on both sides of the channel part 133. According to one embodiment of the present disclosure, the first connection part 131 and the second connection part 132 may be formed by selective conductorization of the active layer 130.

The first connection part 131 and the second connection part 132 are regions where the semiconductor material constituting the active layer 130 is selectively conductorized. Therefore, the first connection part 131 and the second connection part 132 may be referred to as conductorized portions.

By selective conductorization, the electrical conductivity of a selected portion of the active layer 130 may be improved, or electrical conductivity may be provided to the selected portion. The portion of the active layer 130 that is selectively conductorized may have excellent electrical conductivity. Since, by the conductorization, the selected portion of semiconductor layer can have a property close to metal, the conductorization may also be referred to as metallization.

Selective conductorization of the active layer 130 may be achieved by dopant doping, dry etching, or plasma treatment.

According to one embodiment of the present disclosure, in the process of forming a contact hole for connecting the source electrode 161 and the drain electrode 162 to the active layer 130, wet etching and dry etching may be performed, and as a result, a part of the active layer 130 may be conductorized.

However, one embodiment of the present disclosure is not limited thereto, and selective conductorization may be achieved by dopant ion implantation using the gate electrode 150 as a mask. In detail, selective conductorization may be achieved by doping a selected region of the active layer 130 with a dopant. The dopant may include at least one of boron (B), phosphorus (P), fluorine (F), arsenic (As), and hydrogen (H).

Referring to FIG. 1, the active layer 130 may include a first protection part 134 and a second protection part 135.

The first protection part 134 may contact the first connection part 131. The first connection part 131 may be disposed between the channel part 133 and the first protection part 134. The first protection part 134 is covered by a gate insulating layer 140. The second protection part 135 may contact the second connection part 132. The second connection part 132 may be disposed between the channel part 133 and the second protection part 135. The second protection part 135 is covered by a gate insulating layer 140.

According to the example shown in FIG. 1, the channel part 133 has a slope in its entire length, and each of the first connection part 131 and the second connection part 132 has a flat structure. However, one embodiment of the present disclosure is not limited thereto, and the channel part 133 may have a flat part. When the channel part 133 is expanded to a flat area, the channel part 133 may have a flat part. For example, the channel part 133 can have a flat part at the first side S1 or can have a flat part at the second side S2.

Depending on the patterning form of the gate insulating layer 140, at least one of the first protection part 134 and the second protection part 135 may not exist. If contact holes formed in the gate insulating layer 140 expose both ends of the active layer 130, the first protection part 134 and the second protection part 135 may not be formed.

The gate insulating layer 140 is disposed on the active layer 130. The gate insulating layer 140 may include at least one of silicon oxide, silicon nitride, and a metal oxide. The gate insulating layer 140 may have a single layer structure or a multi-layer structure. The gate insulating layer 140 protects the channel part 133. The channel part 133 of the active layer 130 and the gate electrode 150 may be separated from each other by the gate insulating layer 140.

The gate insulating layer 140 may have a patterned shape. For example, the gate insulating layer 140 may be patterned into a shape corresponding to the gate electrode 150. However, one embodiment of the present disclosure is not limited thereto, and the gate insulating layer 140 may be formed to cover the entire upper portion of the substrate 110 except for the contact hole.

Referring to FIG. 1, contact holes may be formed in the gate insulating layer 140. The first connection part 131 and the second connection part 132 may be exposed from the gate insulating layer 140 through the contact holes, respectively. The gate insulating layer 140 may be patterned to expose the first connection part 131 and the second connection part 132 of the active layer 130.

According to one embodiment of the present disclosure, in the process of patterning the gate insulating layer 140, the active layer 130 may be selectively conductorized, so that a first connection part 131 and a second connection part 132, which are conductorized regions, may be formed. The gate insulating layer 140 may have a slope at a predetermined angle θ with respect to the upper surface of the substrate 110. According to one embodiment of the present disclosure, the angle between the upper surface of the gate insulating layer 140 and the upper surface of the substrate 110 may be referred to as the slope angle of the gate insulating layer 140.

In FIG. 1, a structure in which the gate insulating layer 140 has a slope on the channel part 133 relative to the upper surface of the substrate 110 is illustrated, but one embodiment of the present disclosure is not limited thereto, and the gate insulating layer 140 may have a flat part. When the gate insulating layer 140 extends to a flat part of the active layer 130, the gate insulating layer 140 may have a flat part. The gate insulating layer 140 may have a flat part at the first side S1 of the channel part 133, or may have a flat part at the second side S2 of the channel part 133. The position of the flat part may vary depending on the manufacturing process or manufacturing conditions of the gate insulating layer 140.

The gate electrode 150 is disposed on the gate insulating layer 140.

The gate electrode 150 may include at least one of an aluminum based metal such as aluminum (Al) or an aluminum alloy, a silver based metal such as silver (Ag) or a silver alloy, a copper based metal such as copper (Cu) or a copper alloy, a molybdenum based metal such as molybdenum (Mo) or a molybdenum alloy, chromium (Cr), tantalum (Ta), neodymium (Nd), and titanium (Ti). The gate electrode 150 may also have a multilayer structure including at least two conductive films having different physical properties.

The gate electrode 150 is spaced apart from the active layer 130 and overlaps at least a part of the active layer 130. The gate electrode 150 overlaps at least the channel part 133 of the active layer 130.

The gate electrode 150 and the gate insulating layer 140 may have a slope corresponding to the sloping surface 133s of the channel part 133. For example, the gate electrode 150 may be formed to have a slope at a predetermined angle θ with respect to the upper surface of the substrate.

In FIG. 1, a structure in which the gate electrode 150 has a slope with respect to the upper surface of the substrate 110 is illustrated. However, one embodiment of the present disclosure is not limited thereto, and the gate electrode 150 may have a flat part. When a part of the gate electrode 150 is disposed on a flat part of the gate insulating layer 140, the gate electrode 150 may have a flat part. The gate electrode 150 may have a flat part at the first side S1 of the channel part 133, or may have a flat part at the second side S2 of the channel part 133. The position of the flat part formed on the gate electrode 150 may vary depending on the structure of the gate insulating layer 140.

The source electrode 161 and the drain electrode 162 may be disposed on the gate insulating layer 140. The source electrode 161 and the drain electrode 162 are distinguished for convenience of explanation, and the source electrode 161 and the drain electrode 162 may be interchanged each other.

The source electrode 161 and the drain electrode 162 may each include at least one of molybdenum (Mo), aluminum (Al), chromium (Cr), gold (Au), titanium (Ti), nickel (Ni), neodymium (Nd), copper (Cu), and alloys thereof. The source electrode 161 and the drain electrode 162 may each be formed as a single layer having a metal or an alloy of metals, or may be formed as a multilayer having two or more layers.

The source electrode 161 and the drain electrode 162 may be disposed on the same layer as the gate electrode 150. The source electrode 161 may be connected to the active layer 130 through a contact hole. The drain electrode 162 may be spaced apart from the source electrode 161 and connected to the active layer 130 through another contact hole.

The source electrode 161 is disposed on the gate insulating layer 140 in the same manner as the gate electrode 150, and extends along a side surface of a contact hole formed in the gate insulating layer 140 so as to be in contact with the first connection part 131.

The drain electrode 162 is disposed on the gate insulating layer 140 in the same manner as the gate electrode 150, and extends along the side surface of the contact hole formed in the gate insulating layer 140 so as to be in contact with the second connection part 132.

The source electrode 161 and the drain electrode 162 may be made of the same material as the gate electrode 150 and may be formed together with the gate electrode 150 by the same process.

In order to ensure that the source electrode 161 and the drain electrode 162 may stably contact the first connection part 131 and the second connection part 132, respectively, the gate insulating layer 140 may not be removed on the ends of the active layer 130. Since the gate insulating layer 140 is not removed on the ends of the active layer 130, even if a process error occurs, each of the source electrode 161 and the drain electrode 162 may extend along the side surface of the contact hole formed in the gate insulating layer 140 and stably contact the first connection part 131 and the second connection part 132, respectively.

Since the gate insulating layer 140 is not removed on the ends of the first active layer 130, the first protection part 134 and the second protection part 135 may be formed. Since the first protection part 134 and the second protection part 135 are part of the active layer 130 and are not exposed during the patterning process of the gate insulating layer 140, they may maintain semiconductor characteristic without becoming conductorized.

According to one embodiment of the present disclosure, the first connection part 131 may serve as a source electrode, and the second connection part 132 may serve as a drain electrode.

The thin film transistor 100 according to one embodiment of the present disclosure may include an active layer 130, a gate electrode 150, a source electrode 161, and a drain electrode 162. The active layer 130 is disposed between the substrate 110 and the gate electrode 150, and the gate electrode 150 may be disposed on the upper portion of the active layer 130. In this way, a thin film transistor 100 having a structure in which the gate electrode 150 is disposed on the upper portion of the active layer 130 may be referred to as a thin film transistor having a top gate structure.

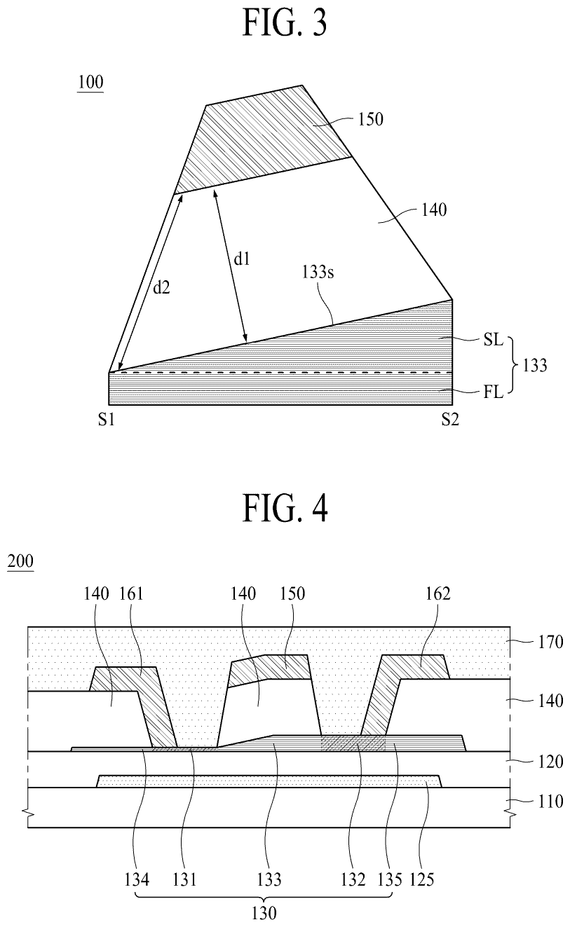

FIG. 3 is a partial cross-sectional view of the channel part 133 and gate electrode 150 of the thin film transistor 100 illustrated in FIG. 1.

In general, thin film transistors having a high-mobility oxide semiconductor layer have the advantage of excellent on-current characteristic, but have the disadvantage that threshold voltage (Vth) variation may occur. For example, when a thin film transistor having a high-mobility oxide semiconductor layer is exposed to high temperature or bias stress is applied thereto, the threshold voltage (Vth) of the thin film transistor having the high-mobility oxide semiconductor layer may decrease or the threshold voltage (Vth) may shift in the negative (−) direction. In addition, unexpected oxygen vacancy (Vo) may occur in the high-mobility oxide semiconductor layer, which may decrease the threshold voltage (Vth) of the thin film transistor and cause a threshold voltage (Vth) roll-off problem, in which current flows through the channel part at a voltage below the designed voltage.

According to one embodiment of the present disclosure, the active layer 130 includes both a first oxide semiconductor layer LM having excellent stability and a second oxide semiconductor layer HM having high mobility characteristic. In addition, referring to FIG. 2 and FIG. 3, due to the sloping surface 133s formed in the active layer 130, both the first oxide semiconductor layer LM and the second oxide semiconductor layer HM may face the gate electrode 150. Accordingly, when the gate electrode 150 is in an ON state, the influence of an electric field generated at the gate electrode 150 can directly affect both the first oxide semiconductor layer LM and the second oxide semiconductor layer HM.

The thin film transistor 100 according to one embodiment of the present disclosure may have both electrical stability due to the first oxide semiconductor layer LM and excellent current characteristic due to the second oxide semiconductor layer HM. In addition, the threshold voltage (Vth) of the thin film transistor 100 may be prevented from shifting in the negative (−) direction.

In addition, since the sloping surface 133s of the channel part 133 faces the gate electrode 150, and the length of the surface of the channel part 133, which faces the gate electrode 150, is increased by the slope, a long channel effect can occur. The channel part 133 of the thin film transistor 100 according to one embodiment of the present disclosure has a structure in which a plurality of first oxide semiconductor layers LM and a plurality of second oxide semiconductor layers HM having different lengths are stacked, and each of the plurality of first oxide semiconductor layers LM and the plurality of second oxide semiconductor layers HM disposed in the channel part 133 can function as a channel. Each of the plurality of channels having different lengths and mobilities included in the channel part 133 can exhibit different threshold voltage effects, and as a result, the threshold voltage range of the channel part 133 is expanded, so that the thin film transistor 100 may have a large s-factor SS.

In addition, the distance d2 between the first side S1 of the channel part 133 and the gate electrode 150 is greater than the distance d1 of the portion of the channel part 133 that is vertically opposed to the gate electrode. As a result, when the gate electrode 150 is turned on, a relatively weak electric field is applied to the first side S1 of the channel part 133. In addition, near the second side S2 of the channel part 133, the length of the second oxide semiconductor layer HM having high mobility characteristic decreases as it goes toward the upper side of the channel part 133. In this way, the threshold voltage range of the channel part 133 is expanded due to the difference in the intensity of the electric field or gate electric field applied to each of the plurality of first oxide semiconductor layers LM and the plurality of second oxide semiconductor layers HM included in the channel part 133, so that the s-factor (S.S) of the thin film transistor 100 can increase.

Due to the driving environment described above, the thin film transistor 100 according to one embodiment of the present disclosure may have a relatively large s-factor, or may have a relatively large subthreshold swing.

In addition, the second side S2 of the channel part 133 contacts the second connection part 132, which is connected to the drain electrode 162, and a high voltage is applied to the drain electrode 162 in the N-type thin film transistor. In the thin film transistor 100 according to one embodiment of the present disclosure, the second side S2 of the channel part 133 disposed at the drain electrode 162 side has a relatively large thickness compared to the first side S1. Due to the large thickness (t1+t2) of the second side S2 of the channel part 133, the voltage stress due to the high voltage applied to the drain electrode 162 may be alleviated.

In order to alleviate voltage stress due to high voltage and secure ON current characteristic, the second side S2 of the channel part 133 may have a thickness of 25 nm or more. In detail, the second side S2 of the channel part 133 may have a thickness in the range of 25 nm to 35 nm, or may also have a thickness of about 30 nm.

In addition, since the second oxide semiconductor layer HM having high mobility characteristic is disposed at the first side S1 of the channel part 133 and a relatively low voltage is applied to the source electrode 161, even though the first side S1 of the channel part 133 has a thin thickness t1, it can sufficiently overcome the voltage stress caused by the voltage applied from the source electrode 161. Accordingly, the first side S1 of the channel part 133, which is disposed at the side of the source electrode 161 can have a relatively small thickness t1.

In detail, in order to secure ON current characteristic, the first side S1 of the channel part 133 may have a thickness of 7 nm or more. In addition, in order to prevent the threshold voltage (Vth) of the thin film transistor 100 from shifting in the negative (−) direction and to secure a large s-factor, the first side S1 of the channel part 133 may have a thickness of 13 nm or less. In detail, the first side S1 of the channel part 133 may have a thickness of 8 to 12 nm, or may have a thickness of about 10 nm.

The thin film transistor 100 according to one embodiment of the present disclosure described above has excellent ON current characteristic and excellent electrical stability, so that the threshold voltage (Vth) may be prevented from shifting in the negative (−) direction. In addition, the thin film transistor 100 may have a large s-factor. Such a thin film transistor 100 may be particularly usefully used as a driving transistor for a display.

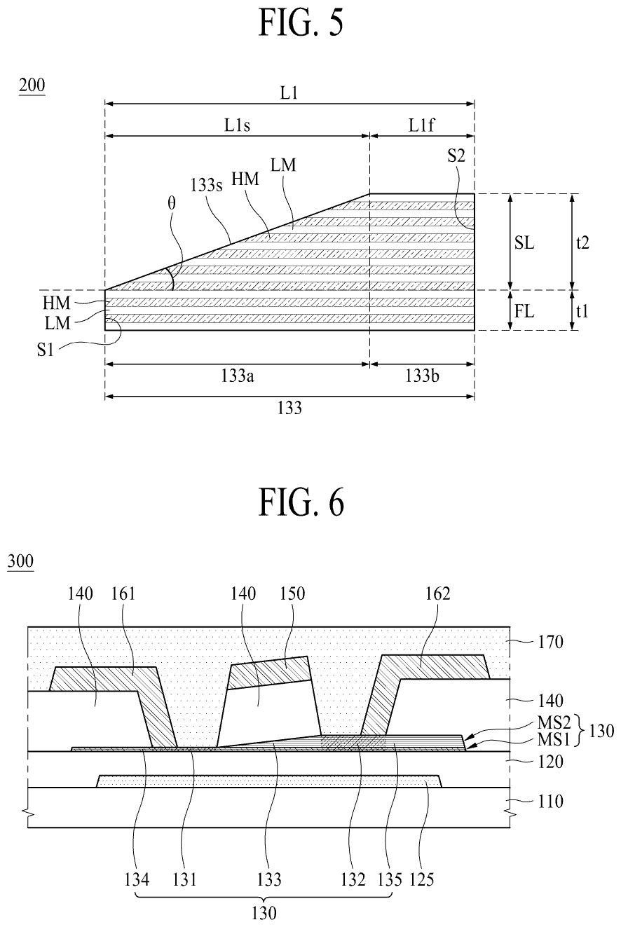

FIG. 4 is a cross-sectional view of a thin film transistor 200 according to another embodiment of the present disclosure, and FIG. 5 is an enlarged cross-sectional view of a channel part 133 of the thin film transistor 200 illustrated in FIG. 4. Hereinafter, to avoid redundancy, a description of the components already described is omitted.

According to another embodiment, the channel part 133 may have a first channel part 133a and a second channel part 133b. The first channel part 133a is connected to the first side S1 and may have a slope. The second channel part 133b is connected to the second side S2 and does not have a slope.

Referring to FIG. 5, the part of the channel part 133 that has a slope may be defined as a first channel part 133a, and the part that does not have a slope may be defined as a second channel part 133b.

The second channel part 133b may have a uniform thickness (t1+t2). In addition, the second channel part 133b may have the same thickness (t1+t2) as the second connection part 132.

The length L1s of the first channel part 133a may be 30% or more of the length L1 of the channel part 133. When the length L1s of the first channel part 133a is less than 30% of the length L1 of the channel part 133, the length L1f of the second channel part 133b may be 70% or more of the channel parts 133, thus can provide excellent ON current characteristic, however, such problems that the threshold voltage (Vth) shifts in a negative (−) direction and the s-factor decreases may arise. In order to prevent the threshold voltage (Vth) of the thin film transistor from shifting in a negative (−) direction, there is a method of increasing the thickness of the first oxide semiconductor layer LM located thereon, however in this case, the mobility of the thin film transistor may decrease.

Meanwhile, if the length L1s of the first channel part 133a having a slope increases, the s-factor S.S may increase due to the difference in lengths of each layer constituting the channel part 133. On the other hand, if the length L1s of the first channel part 133a having a slope decreases, the difference in lengths of each layer constituting the channel part 133 may not be large enough, and thus the effect of increasing the s-factor may not be sufficient.

The length L1s of the first channel part 133a may be 50% or more of the total length L1 of the channel part 133, or may be 60% or more. The length L1s of the first channel part 133a may be 100% of the total length L1 of the channel part 133, and in this case, a channel part 133 as illustrated in FIG. 3 will be formed. Accordingly, the length L1f of the second channel part 133b may be 0.

For example, when the length L1 of the channel part 133 is 6 μm, the length L1s of the first channel part 133a may be 2 μm or more. When the thin film transistor 200 is designed in this manner, the threshold voltage (Vth) of the thin film transistor 200 may be prevented from shifting in the negative (−) direction, and the thin film transistor 200 may have a large s-factor.

The slope angle θ of the first channel part 133a may vary depending on the length L1 of the channel part 133 and the length of the first channel part 133a. As already described, the slope angle θ of the first channel part 133a may be defined as the angle between the upper surface of the substrate 110 and the sloping surface 133s formed on the first channel part 133a.

The slope angle θ may be in the range of 0.15° to 0.60°. The slope angle θ may be in the range of 0.19° to 0.57°. Within this range of angles of slope, the length L1s of the first channel part 133a may be 30% or more of the length L1 of the channel part 133.

Referring to FIG. 4, the gate insulating layer 140 may have a slope part and a flat part. The gate insulating layer 140 may have a slope part and a flat part between the channel part 133 of the active layer 130 and the gate electrode 150. In detail, the gate insulating layer 140 may have a slope part on the first channel part 133a and a flat part on the second channel part 133b.

Referring to FIG. 4, the gate electrode 150 may have a slope part and a flat part. In detail, the gate electrode 150 may have a slope part on the first channel part 133a and a flat part on the second channel part 133b.

FIG. 6 is a cross-sectional view of a thin film transistor 300 according to another embodiment of the present disclosure.

The thin film transistor 300 of FIG. 6 may further include a third oxide semiconductor layer MS1 compared to the thin film transistor 100 of FIG. 1.

Referring to FIG. 6, the active layer 130 may include a third oxide semiconductor layer MS1 that serves as a support and a stacked oxide semiconductor layer MS2 on the third oxide semiconductor layer MS1.

The stacked oxide semiconductor layer MS2 includes a plurality of first oxide semiconductor layers LM and a plurality of second oxide semiconductor layers HM. In the stacked oxide semiconductor layer MS2, the plurality of first oxide semiconductor layers LM and the plurality of second oxide semiconductor layers HM may be alternately stacked. In addition, the second oxide semiconductor layer HM has a higher mobility than the first oxide semiconductor layer LM.

The stacked oxide semiconductor layer MS2 may have a slope. The slope may be formed across a plurality of first oxide semiconductor layers LM and a plurality of second oxide semiconductor layers HM. In detail, the stacked oxide semiconductor layer MS2 located in the channel part 133 may have a slope.

The third oxide semiconductor layer MS1 serves as a support layer. The third oxide semiconductor layer MS1 can support and protect the stacked oxide semiconductor layer MS2. The third oxide semiconductor layer MS1 may be made of an oxide semiconductor material with high stability. The third oxide semiconductor layer MS1 may be made of, for example, the same material as the first oxide semiconductor layer LM.

The third oxide semiconductor layer MS1 may be selectively conductorized at the first connection part 131 and the second connection part 132. As a result, when the thin film transistor 300 is in an ON state, current can flow smoothly between the source electrode 161 and the drain electrode 162.

The third oxide semiconductor layer MS1 may have a thickness of 20 nm or less. In detail, the third oxide semiconductor layer MS1 may have a thickness of 15 nm or less, and may also have a thickness of about 10 nm.

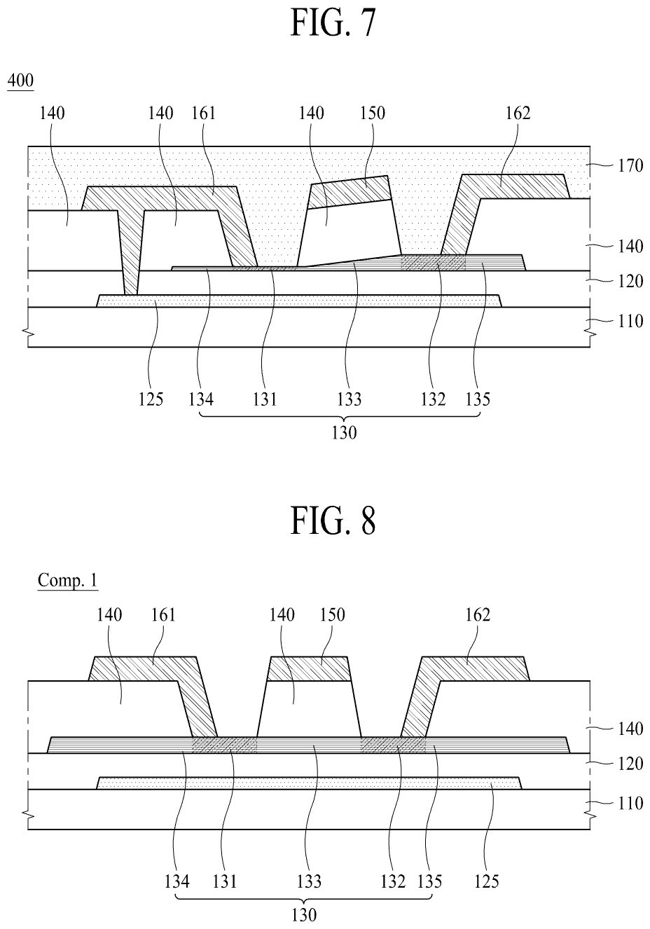

FIG. 7 is a cross-sectional view of a thin film transistor 400 according to another embodiment of the present disclosure.

The thin film transistor 400 of FIG. 7 has a laminated structure substantially the same as that of the thin film transistor 100 of FIG. 1, but, compared to the thin film transistor 100 of FIG. 1, the source electrode 161 may be connected to the light shielding layer 125.

In detail, the configuration of the active layer 130 in the thin film transistor 400 of FIG. 7 is substantially the same as the configuration of the active layer 130 included in the thin film transistor 100 of FIG. 1. In the thin film transistor 400 of FIG. 7, the source electrode 161 may be connected to the light shielding layer 125 through a contact hole formed to penetrate the gate insulating layer 140 and the buffer layer 120.

By connecting the light shielding layer 125 to the source electrode 161, the light shielding layer 125 may be prevented from being left in a floating state. As a result, the electrical stability of the light shielding layer 125 may be improved, and the electrical stability of the thin film transistor 400 may be improved.

Referring to FIG. 7, the channel part 133 may have a flat part. In detail, the channel part 133 disposed toward the first connection part 131 may have a flat part. However, another embodiment of the present disclosure is not limited thereto, and the channel part 133 disposed toward the second connection part 132 may also have a flat part. The position of the flat part formed in the channel part 133 may vary depending on the arrangement of the gate insulating layer 140.

Referring to FIG. 7, a portion of the gate insulating layer 140 may be formed on a flat part of the active layer 130. In detail, between the active layer 130 and the gate electrode 150, the gate insulating layer 140 may be disposed on the flat part of the active layer 130. In this case, the flat part of the active layer 130 overlapping the gate insulating layer 140 may become a flat part of the channel part 133.

FIG. 8 is a cross-sectional view of a thin film transistor (Comp. 1) according to a comparative example.

The thin film transistor (Comp. 1) according to a comparative example has a channel part 133 of an active layer 130 that does not have a slope, compared to the thin film transistor 100 of FIG. 1. In detail, it includes a plurality of first oxide semiconductor layers LM and a plurality of second oxide semiconductor layers HM that are alternately stacked.

The channel part 133 of the active layer 130 included in the thin film transistor (Comp. 1) according to the comparative example does not have a slope and has substantially the same thickness over the entire area of the active layer 130.

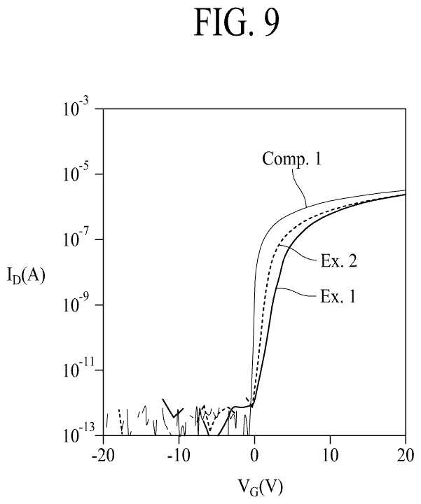

FIG. 9 is a voltage-current graph for thin film transistors. In FIG. 9, “Comp. 1” represents a value measured for a thin film transistor (Comp. 1) according to the comparative example illustrated in FIG. 8, “Ex. 1” represents a value measured for a thin film transistor 100 illustrated in FIG. 1, and “Ex. 2” represents a value measured for a thin film transistor 200 illustrated in FIG. 4.

In the thin film transistors (Comp. 1, 100, 200) that were subjects to the graph of FIG. 9, eight first oxide semiconductor layers LM each having a thickness of 2.0 nm and seven second oxide semiconductor layers HM each having a thickness of 2.0 nm were alternately laminated to form an active layer 130. The length of the channel part 133 was set to 6 μm in all cases.

In the thin film transistor 100 (Ex. 1) of FIG. 1 and the thin film transistor 200 (Ex. 2) of FIG. 4, the active layer 130 was etched to form a slope in the channel part 133. In the thin film transistor 100 (Ex. 1) of FIG. 1, a slope was formed over the entire channel part 133. In the thin film transistor 200 (Ex. 2) of FIG. 4, the length L1s of the first channel part 133a having the sloping surface 133s was set to 4 μm, and the length of the second channel part 133b not having the sloped surface was set to 2 μm. In the thin film transistor (Comp. 1) according to the comparative example, no slope was formed over the entire length 6 μm of the channel part 133.

The graphs shown in FIG. 9 illustrate the current ID of the thin film transistor with respect to the gate voltage VG. The gate voltage VG is measured as the voltage Vos between the gate electrode 150 and the source electrode 161, and the current Ip of the thin film transistor is measured as the current Ips between the drain electrode 162 and the source electrode 161. The measurement results are as shown in FIG. 9. In addition, the values of the threshold voltage (Vth) and the s-factor (subthreshold swing, S.S) measured for each thin film transistor are shown in Table 1 below.

TABLE 1

| Classification | Vth (threshold voltage) V | S. S (s-factor) |
|---|---|---|
| Comp. 1 | 0.00 | 0.12 |
| Ex. 1 | 1.8 | 0.5 |
| Ex. 2 | 1.1 | 0.27 |

Referring to FIG. 9, the thin film transistor 100, 200 according to the embodiments of the present disclosure has a large s-factor (S.S) and a positive (+) threshold voltage (Vth) compared to the thin film transistor (Comp. 1) according to the comparative example.

Since the thin film transistor 100, 200 according to embodiments of the present disclosure has a positive threshold voltage (Vth), a negative shift of the threshold voltage (Vth) of the thin film transistor may be prevented. As a result, there is no difficulty in achieving the ON voltage of the thin film transistor, and the thin film transistor can perform a stable switching function.

In addition, the thin film transistor 100, 200 according to the embodiments of the present disclosure has an advantage in the expression of the gray scale because it has a relatively large s-factor (S.S). Therefore, the thin film transistor 100, 200 according to the embodiments of the present disclosure may be applied to a driving transistor of a display apparatus, and a display apparatus including such a thin film transistor can easily express and control the gray scale of a pixel.

Hereinafter, a manufacturing method for a thin film transistor will be described with reference to the drawings.

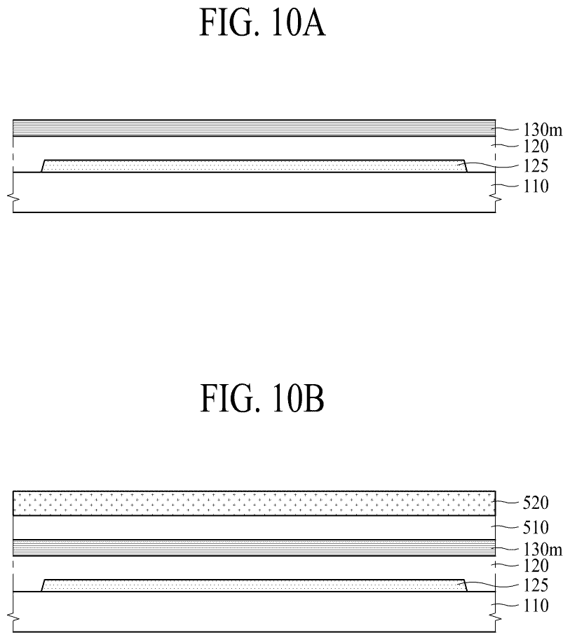

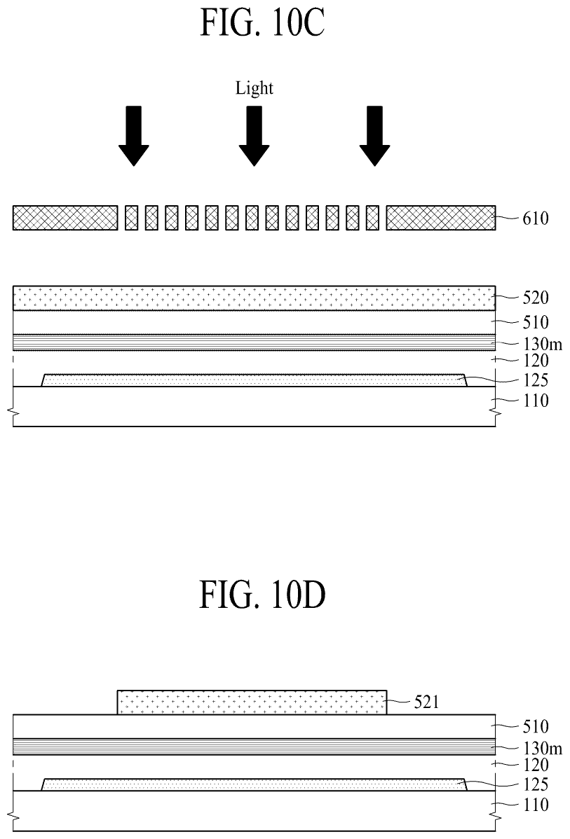

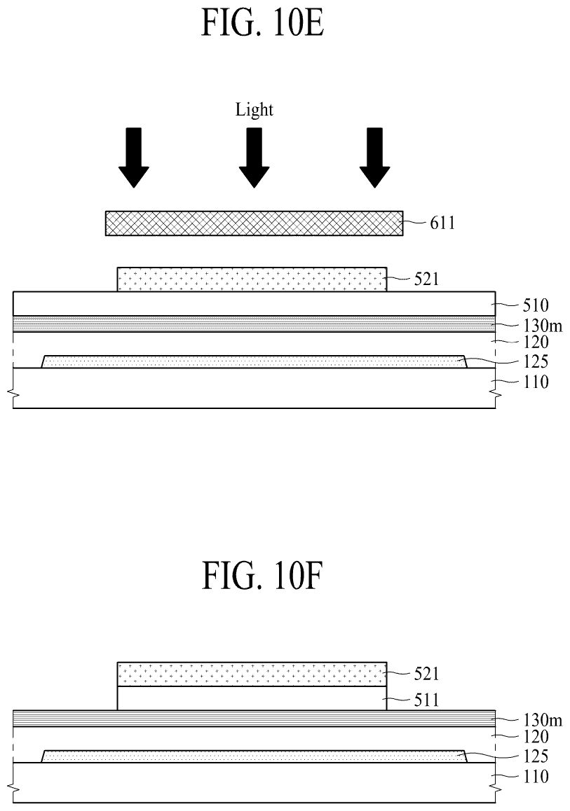

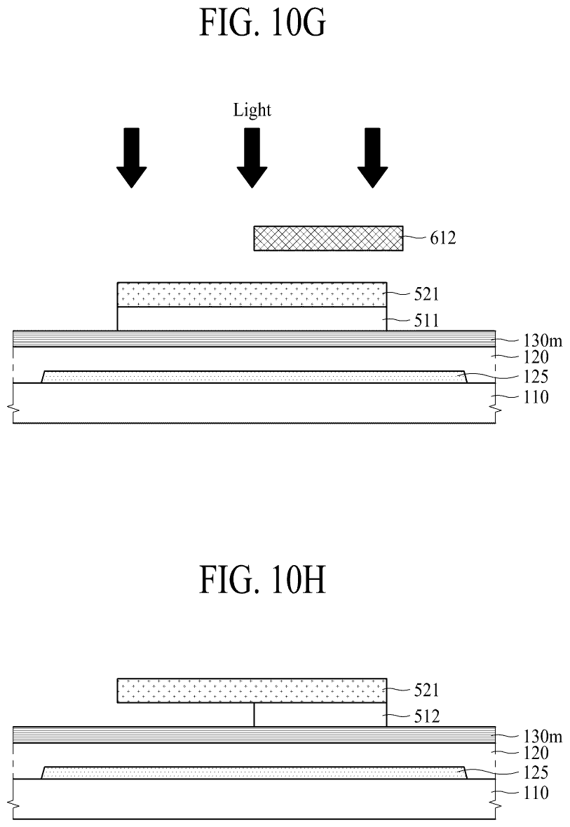

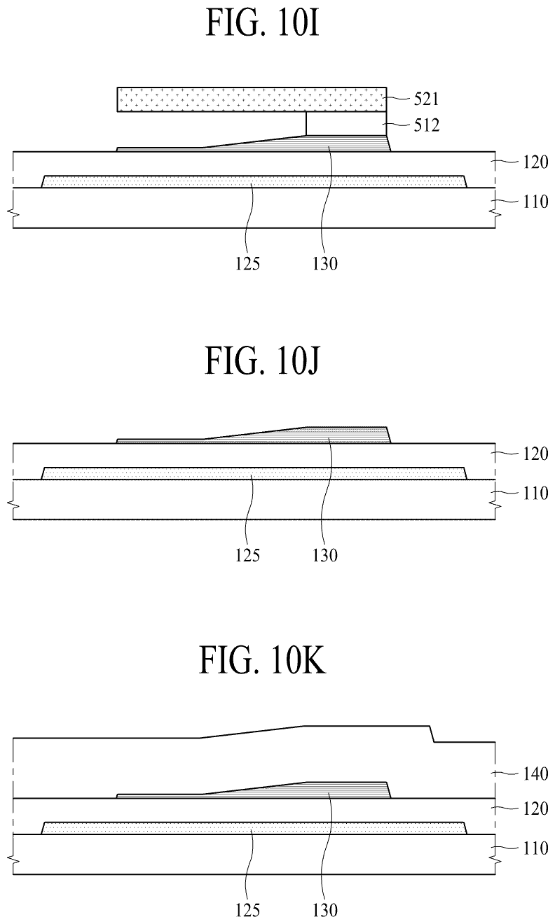

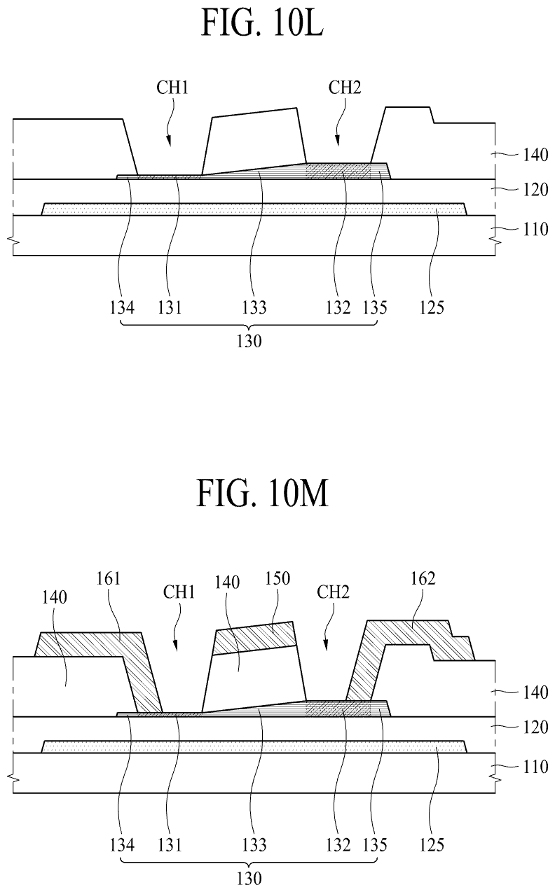

FIG. 10A to FIG. 10M are cross-sectional views illustrating a manufacturing method for a thin film transistor 100 according to one embodiment of the present disclosure.

Referring to FIG. 10A, a light shielding layer 125 is formed on a substrate 110, a buffer layer 120 is formed on the light shielding layer 125, and an oxide semiconductor material layer 130m is formed on the buffer layer 120. The light shielding layer 125 and the buffer layer 120 may be omitted. When the light shielding layer 125 and the buffer layer 120 are omitted, the oxide semiconductor material layer 130m may be formed on the substrate 110.

The forming an oxide semiconductor material layer 130m may include alternately stacking a plurality of first oxide semiconductor material layers and a plurality of second oxide semiconductor material layers. Here, the second oxide semiconductor material layer may have a greater mobility than the first oxide semiconductor material layer. According to one embodiment of the present disclosure, for example, by controlling the concentration of oxygen during the deposition of the active layer, a plurality of high-mobility oxide semiconductor layers and a plurality of low-mobility oxide semiconductor layers having thin thicknesses can be alternately stacked.

Referring to FIG. 10B, a positive photoresist layer 510 and a negative photoresist layer 520 are formed on an oxide semiconductor material layer 130m.

Referring to FIG. 10C, a halftone mask 610 is disposed on a positive photoresist layer 510 and a negative photoresist layer 520, and light is irradiated onto the halftone mask 610. Accordingly, the positive photoresist layer 510 and the negative photoresist layer 520 are exposed to light (first exposure). The halftone mask 610 includes a light shielding part and a semi-transmissive part.

Referring to FIG. 10D, the positive photoresist layer 510 and the negative photoresist layer 520 are developed (first development). As a result of the development, a portion of the negative photoresist layer 520, that has been semi-transparently exposed by the semi-transmissive part of the halftone mask 610, remains, and a negative photoresist pattern 521 is formed.

The negative photoresist pattern 521 is a portion that has been cured by exposure, and other portions of the negative photoresist layer 520 are removed by development because they have not been exposed to light. The positive photoresist layer 510 is not removed by development because it has not been directly irradiated with light.

Referring to FIG. 10E, a photomask 611 is disposed on a negative photoresist pattern 521, and light is irradiated from above the photomask 611. Accordingly, the positive photoresist layer 510 is exposed (second exposure).

Referring to FIG. 10F, the negative photoresist pattern 521 and the positive photoresist layer 510 are developed (second development). Through development, the exposed portion of the positive photoresist layer 510 is removed, forming a positive photoresist pattern 511.

As a result, as illustrated in FIG. 10F, a positive photoresist pattern 511 and a negative photoresist pattern 521 are formed on the oxide semiconductor material layer 130m. The negative photoresist pattern 521 is in a cured state by exposure using the halftone mask 610 illustrated in FIG. 10C.

Referring to FIG. 10G, a photomask 612 is disposed on the positive photoresist pattern 511 and the negative photoresist pattern 521, and light is irradiated on the photomask 612. Accordingly, the positive photoresist pattern 511 and the negative photoresist pattern 521 are partially exposed (third exposure).

Referring to FIG. 10H, the partially exposed positive photoresist pattern 511 and negative photoresist pattern 521 are developed (third development). Accordingly, the exposed portion of the positive photoresist pattern 511 is removed. Accordingly, the positive photoresist pattern 512 and negative photoresist pattern 521 are completed.

The positive photoresist pattern 511 illustrated in FIG. 10F may be referred to as a primary pattern or a first pattern, and the positive photoresist pattern 512 illustrated in FIG. 10H may be referred to as a secondary pattern or a second pattern.

Referring to FIG. 10I, the oxide semiconductor material layer 130m is etched using the positive photoresist pattern 512 and negative photoresist pattern 521 as masks, and as a result, the active layer 130 illustrated in FIG. 10I is formed.

Referring to FIG. 10J, the positive photoresist pattern 512 and the negative photoresist pattern 521 are removed. Referring to FIG. 10J, the active layer 130 has a sloped surface.

Referring to FIG. 10K, a gate insulating layer 140 is formed on the active layer 130.

Referring to FIG. 10L, contact holes CH1, CH2 are formed in the gate insulating layer 140. During the process of forming the contact holes CH1, CH2, selective conductorization is performed to the active layer 130, thereby forming a first connection part 131 and a second connection part 132. The area where the channel part 133 is to be formed may be determined by the contact holes CH1, CH2. The channel part 133 is formed between the first connection part 131 and the second connection part 132.

Referring to FIG. 10M, a gate electrode 150 is formed on a gate insulating layer 140. In addition, a source electrode 161 and a drain electrode 162 are formed on the gate insulating layer 140.

The gate electrode 150 overlaps with the channel part 133. The portion of the active layer 130 that overlaps with the gate electrode 150 may become the channel part 133.

The source electrode 161 is formed on the gate insulating layer 140 and extends along the side of the contact hole CH1 formed in the gate insulating layer 140 so as to be in contact with the first connection part 131 of the active layer 130.

The drain electrode 162 is disposed on the gate insulating layer 140 and extends along the side of the contact hole CH2 formed in the gate insulating layer 140 so as to be in contact with the second connection part 132 of the active layer 130.

In addition, referring to FIG. 10M, the channel section 133 has a slope.

The thin film transistor 100 according to one embodiment of the present disclosure may be manufactured by the method described above.

Hereinafter, the display apparatus including the above-described thin film transistor will be described.

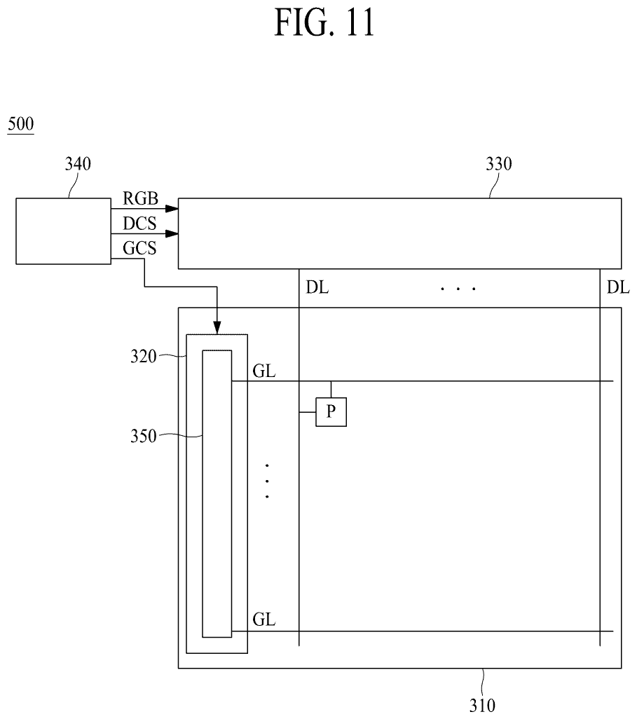

FIG. 11 is a schematic diagram of a display apparatus 500 according to another embodiment of the present disclosure.

The display apparatus 500 may include a display panel 310, a gate driver 320, a data driver 330, and a control unit 340.

The gate lines GL and data lines DL are disposed on the display panel 310, and pixels P are arranged in the intersection area of the gate lines GL and data lines DL. An image is displayed by driving the pixels P.

The control unit 340 controls the gate driver 320 and the data driver 330.

The control unit 340 uses signals supplied from an external system to output a gate control signal GCS for controlling the gate driver 320 and a data control signal DCS for controlling the data driver 330. In addition, the control unit 340 samples input image data input from the external system, rearranges it, and supplies the rearranged image data RGB to the data driver 330.

The gate control signal GCS may include a gate start pulse GSP, a gate shift clock GSC, a gate output enable signal GOE, a start signal Vst, a gate clock GCLK, etc. In addition, the gate control signal GCS may include control signals for controlling a shift register.

The data control signal DCS may include a source start pulse SSP, a source shift clock signal SSC, a source output enable signal SOE, a polarity control signal POL, etc.

The data driver 330 supplies data voltage to the data lines DL of the display panel 310. In detail, the data driver 330 can convert image data RGB input from the control unit 340 into analog data voltage and supply the data voltage to the data lines DL.

The gate driver 320 sequentially supplies gate pulses GP to the gate lines GL during one frame. Here, one frame refers to a period during which one image is output through the display panel. In addition, the gate driver 320 supplies a gate-off signal Goff capable of turning off the switching element to the gate lines GL during the remaining period during which the gate pulse GP is not supplied during one frame. Hereinafter, the gate pulse GP and the gate-off signal Goff are collectively referred to as a scan signal SS.

The gate driver 320 may be mounted on the substrate 110. In this way, a structure in which the gate driver 320 is directly mounted on the substrate 110 is called a Gate In Panel (GIP) structure.

The gate driver 320 includes a plurality of thin film transistors. The gate driver 320 may include the thin film transistors 100, 200, 300, 400 described above.

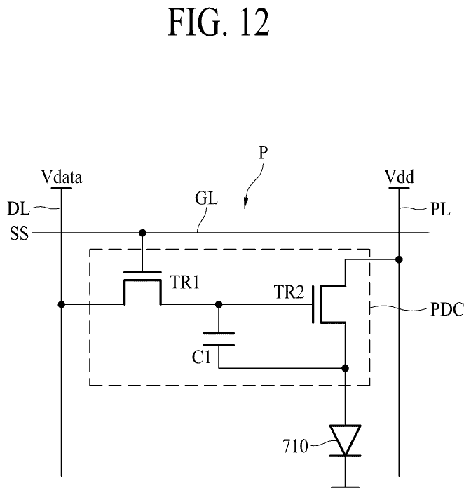

FIG. 12 is a circuit diagram for one pixel P of FIG. 11.

The circuit diagram of FIG. 12 is an equivalent circuit diagram for a pixel P of a display apparatus 500 including an organic light emitting diode (OLED) as a display element 710.

The pixel P includes a display element 710 and a pixel driver PDC that drives the display element 710. The pixel driver PDC includes a first thin film transistor TR1 and a second thin film transistor TR2.

A thin film transistor 100, 200, 300, 400 according to embodiments of the present disclosure may be applied as the first thin film transistor TR1 of FIG. 12, and a thin film transistor 100, 200, 300, 400 according to embodiments of the present disclosure may be applied as the second thin film transistor TR2.

The first thin film transistor TR1 is connected to a gate line GL and a data line DL, and is turned on or off by a scan signal SS supplied through the gate line GL.

The data line DL provides a data voltage Vdata to the pixel driver PDC, and the first thin film transistor TR1 controls the application of the data voltage Vdata.

The driving power line PL provides a driving voltage Vdd to the display element 710, and the second thin film transistor TR2 controls the driving voltage Vdd. The driving voltage Vdd is a pixel driving voltage for driving the organic light emitting diode (OLED), which is the display element 710.

When the first thin film transistor TR1 is turned on by a scan signal SS applied through the gate line GL from the gate driver 320, the data voltage Vdata supplied through the data line DL is supplied to the gate electrode of the second thin film transistor TR2 connected to the display element 710. The data voltage Vdata is charged in the first capacitor C1 formed between the gate electrode and the source electrode of the second thin film transistor TR2. The first capacitor C1 is a storage capacitor Cst.

The amount of current supplied to the organic light emitting diode (OLED), which is the display element 710, through the second thin film transistor TR2 is controlled according to the data voltage Vdata, and accordingly, the gradation of light output from the display element 710 may be controlled.

pixel driver PDC according to another embodiment of the present disclosure may be formed in various structures other than the structures described above. For example, the pixel driver PDC may include three or more thin film transistors and two or more capacitors.

The present disclosure described above is not limited to the above-described embodiments and the attached drawings, and it will be apparent to a person skilled in the art to which the present disclosure pertains that various substitutions, modifications, and changes are possible within a scope that does not depart from the technical details of the present disclosure.

A thin film transistor according to one embodiment of the present disclosure may have excellent current characteristic, excellent stability, and a large s-factor.

According to one embodiment of the present disclosure, high-mobility oxide semiconductor layers and low-mobility oxide semiconductor layers are alternately laminated to form an active layer, and a slope is formed in a channel part of the active layer, so that the thin film transistor may have excellent current characteristic and a large s-factor at the same time.

The thin film transistor according to one embodiment of the present disclosure may have excellent current characteristic and excellent driving stability by including a plurality of high-mobility oxide semiconductor layers and a plurality of low-mobility oxide semiconductor layers alternately disposed.

According to one embodiment of the present disclosure, by controlling the concentration of oxygen during the manufacturing process of the active layer, a plurality of high-mobility oxide semiconductor layers and a plurality of low-mobility oxide semiconductor layers having thin thicknesses may be disposed at desired positions, thereby enabling the thin film transistor to have excellent current characteristic and excellent stability.

According to one embodiment of the present disclosure, the thin film transistor may have excellent current characteristic by high mobility oxide semiconductor layers, while the threshold of the thin film transistor may be prevented from shifting in the negative direction.

A display apparatus according to one embodiment of the present disclosure including the above thin film transistor may be manufactured with high resolution and have stable and excellent display characteristic.

In addition to the effects mentioned above, other features and advantages of the present disclosure are described below or may be clearly understood by those skilled in the art to which the present disclosure pertains from such description and explanation.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
an active layer including a plurality of first oxide semiconductor layers and a plurality of second oxide semiconductor layers; and
a gate electrode spaced apart from the active layer and at least partially overlapping the active layer,
wherein the active layer includes a channel part overlapping the gate electrode,
wherein the channel part has a slope part, and
wherein the second oxide semiconductor layer has a higher mobility than the first oxide semiconductor layer.

2. The thin film transistor of claim 1,
wherein the plurality of first oxide semiconductor layers and the plurality of second oxide semiconductor layers are alternately stacked.

3. The thin film transistor of claim 1,
wherein an oxygen content ratio of the first oxide semiconductor layer is higher than an oxygen content ratio of the second oxide semiconductor layer,
wherein the oxygen content ratio of the first oxide semiconductor layer is calculated, on a molar basis, as a ratio of the oxygen element to the total elements contained in the first oxide semiconductor layer, and
wherein the oxygen content ratio of the second oxide semiconductor layer is calculated, on a molar basis, as a ratio of the oxygen element to the total elements contained in the second oxide semiconductor layer.

4. The thin film transistor of claim 1,
wherein each of the plurality of first oxide semiconductor layers and each of the plurality of second oxide semiconductor layers has a thickness of 1.5 to 2.5 nm.

5. The thin film transistor of claim 1,
wherein the first oxide semiconductor layer includes at least one of IGZO (InGaZnO) based oxide semiconductor material, GZO (GaZnO) based oxide semiconductor material, IGO (InGaO) based oxide semiconductor material, or GZTO (GaZnSnO) based oxide semiconductor material, and
wherein, when the oxide semiconductor material included in the first oxide semiconductor layer contains gallium (Ga) and indium (In), the concentration of gallium (Ga) is higher than the concentration of indium (In) on a molar basis.

6. The thin film transistor of claim 1,
wherein the second oxide semiconductor layer includes at least one of InO based oxide semiconductor material, IZO (InZnO) based oxide semiconductor material, IGO (InGaO) based oxide semiconductor material, ITZO (InSnZnO) based oxide semiconductor material, IGZO (InGaZnO) based oxide semiconductor material, IGZTO (InGaZnSnO) based oxide semiconductor material, FIGZO (FelnGaZnO) based oxide semiconductor material, or FIZO (FeInZnO) based oxide semiconductor material, and
wherein, when the oxide semiconductor material included in the second oxide semiconductor layer contains gallium (Ga) and indium (In), the concentration of indium (In) is higher than the concentration of gallium (Ga) on a molar basis.

7. The thin film transistor of claim 1,
wherein the active layer comprises:
a first connection part connected to a first side of the channel part; and
a second connection part connected to a second side of the channel part,
wherein a thickness of the first side is smaller than a thickness of the second side.

8. The thin film transistor of claim 7,
wherein the first connection part is connected to a source electrode, and
wherein the second connection part is connected to a drain electrode.

9. The thin film transistor of claim 7,
wherein a thickness of the channel part gradually increases from the first side toward the second side.

10. The thin film transistor of claim 7,
wherein a total number of the first oxide semiconductor layers disposed at the second side is greater than the total number of the first oxide semiconductor layers disposed at the first side, and
wherein a total number of the second oxide semiconductor layers disposed at the second side is greater than the total number of second oxide semiconductor layers disposed at the first side.

11. The thin film transistor of claim 1,
wherein the channel part includes a flat part adjacent to the slope part.

12. The thin film transistor of claim 1,
wherein the gate electrode includes a slope part corresponding to the slope part of the channel part.

13. The thin film transistor of claim 1 further comprising:
a gate insulating layer between the active layer and the gate electrode,
wherein the gate insulating layer includes a slope part corresponding to the slope part of the channel part.

14. The thin film transistor of claim 7,
wherein the channel part has a first channel part and a second channel part,
wherein the first channel part is connected to the first side and has a slope part, and
wherein the second channel part is connected to the second side and has no slope part.

15. The thin film transistor of claim 14,
wherein a thickness of the second channel part is uniform, and
wherein the thickness of the second channel part is equal to a thickness of the second connection part.

16. The thin film transistor of claim 14,
wherein the gate electrode has a slope part and a flat part.

17. The thin film transistor of claim 14 further comprising:
a gate insulating layer between the active layer and the gate electrode, and
wherein the gate insulating layer has a slope part and a flat part.

18. A manufacturing method of a thin film transistor comprising:
forming an oxide semiconductor material layer on a substrate;
forming a positive photoresist pattern and a negative photoresist pattern on the oxide semiconductor material layer;
partially exposing the positive photoresist pattern and the negative photoresist pattern;
developing the partially exposed positive photoresist pattern and the negative photoresist pattern;
etching the oxide semiconductor material layer using the developed positive photoresist pattern and the negative photoresist pattern as a mask to form an active layer; and
forming a gate electrode spaced apart from the active layer on the active layer,
wherein forming the oxide semiconductor material layer comprises alternately stacking a plurality of first oxide semiconductor material layers and a plurality of second oxide semiconductor material layers,
wherein in developing the positive photoresist pattern and the negative photoresist pattern, an exposed portion of the positive photoresist pattern is removed,
wherein the second oxide semiconductor layer has a higher mobility than the first oxide semiconductor layer,
wherein the active layer includes a channel part overlapping the gate electrode, and
wherein the channel part has a sloping surface.

19. A display apparatus comprising the thin film transistor according to claim 1.

20. A thin film transistor comprising:
a substrate;
an active layer on the substrate and including a plurality of first oxide semiconductor layers and a plurality of second oxide semiconductor layers that are alternately stacked;
a gate insulating layer on the active layer; and
a gate electrode on the active layer and at least partially overlapping the active layer,
wherein the active layer includes:
a channel part overlapping the gate electrode;
a first connection part connected to a first side of the channel part; and
a second connection part connected to a second side of the channel part,
wherein a thickness of the first side of the channel part is smaller than a thickness of the second side of the channel part,
wherein the first connection part is configured to be connected to a source electrode, and the second connection part is configured to be connected to a drain electrode and
wherein the second oxide semiconductor layer has a higher mobility than the first oxide semiconductor layer.

21. The thin film transistor of claim 20, wherein the channel part has a slope part between the first connection part and the second connection part.
